(19) United States
(12) Patent Application Publication
(10) Pub. No.: US 2025/0176144 A1
(43) Pub. Date: May 29, 2025

(54) HEAT DISSIPATION STRUCTURE

(71) Applicant: SILICONWARE PRECISION INDUSTRIES CO., LTD., Taichung City (TW)

(72) Inventors: Meng-Lin WU, Taichung City (TW); Hui-Lung CHEN, Taichung City (TW); Wu-Su CHEN, Taichung City (TW)

(73) Assignee: SILICONWARE PRECISION INDUSTRIES CO., LTD., Taichung City (TW)

(21) Appl. No.: 18/654,063

(22) Filed: May 3, 2024

(30) Foreign Application Priority Data
Nov. 27, 2023 (TW) 112145867

(51) Int. Cl. H05K 7/20; G01R 1/04

(52) U.S. Cl. CPC H05K 7/2039; G01R 1/0458; H05K 7/20154

(57) ABSTRACT

A heat dissipation structure is provided and includes: bonding portions disposed on electronic elements on an electronic carrier board of a test apparatus; and a board body having a first side and a second side opposing the first side, and the board body is disposed on the bonding portions via the first side and formed with heat transfer members on the second side.

### BACKGROUND

### 1. Technical Field

The present disclosure relates to a heat dissipation structure, and more particularly, to a heat dissipation structure disposed in a test apparatus.

### 2. Description of Related Art

Nowadays, many electronic devices (such as smartphones) transmit signals through wireless communication technologies (such as 4G, 5G wireless communication technologies, etc.), and when these electronic devices transmit and receive electromagnetic energy, they often interfere with each other due to signal frequencies and power spectrum density, so these electronic devices must comply with the specifications of various wireless communication technology standards.

Therefore, these electronic devices are required to ensure that they comply with various standard-based specifications specified in mobile communication technology when designing, and these electronic devices need to pass high-standard testing when entering mass production to avoid defects generated during the production process that cause the product to malfunction.

FIG. 1 is a schematic diagram of a conventional test apparatus 1. The test apparatus 1 comprises a handler 11, a test socket 12 connected to the handler 11, and an electronic carrier board 13 disposed on the test socket 12. In the conventional test apparatus 1, electronic elements 14 are disposed on the electronic carrier board 13 for testing. However, the electronic elements 14 will generate high heat during testing, and the electronic elements 14 will be exposed to a high temperature test environment for a long time without heat dissipation elements, which may easily lead to shortcomings such as shortened service life and early damage.

Therefore, there is a need for a solution that addresses the aforementioned shortcomings in the prior art.

### SUMMARY

In view of the aforementioned shortcomings of the prior art, the present disclosure provides a heat dissipation structure for a test apparatus, the heat dissipation structure comprises: bonding portions disposed on electronic elements on an electronic carrier board of the test apparatus; and a board body having a first side and a second side opposing the first side, wherein the board body is disposed on the bonding portions via the first side and formed with heat transfer members on the second side.

In the aforementioned heat dissipation structure, a material of the board body is metal alloy.

In the aforementioned heat dissipation structure, the metal alloy is aluminum alloy.

In the aforementioned heat dissipation structure, each of the bonding portions is a thermal pad.

In the aforementioned heat dissipation structure, the present disclosure further comprises a frame surrounding the board body.

In the aforementioned heat dissipation structure, the frame has a mounting hole for installing thermocouple circuits.

In the aforementioned heat dissipation structure, each of the heat transfer members is a plurality of fins spaced apart from and parallel to each other.

In the aforementioned heat dissipation structure, the present disclosure further comprises a blowing member disposed above the second side of the board body and blowing air toward the heat transfer members.

As can be understood from the above, the heat dissipation structure of the present disclosure can be disposed on the electronic elements of the electronic carrier board of the test apparatus, which can effectively reduce the temperature of the electronic elements and enable the electronic elements to operate at a lower temperature, and also reduce the service life shortening and damage of the electronic elements caused by temperature, while ensuring the stability and reliability of temperature-sensitive elements during testing. In addition, the board body of the heat dissipation structure of the present disclosure is made of metal alloy, which can also avoid warpage.

### BRIEF DESCRIPTION OF THE DRAWINGS

FIG. 1 is a schematic view of a conventional test apparatus.

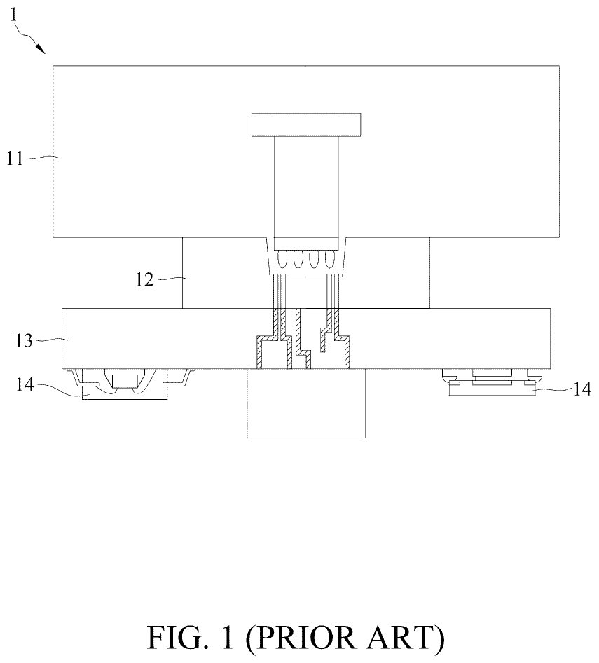

FIG. 2 is an overall schematic view of a heat dissipation structure of the present disclosure disposed in the test apparatus.

FIG. 3 is a schematic top view of the heat dissipation structure of the present disclosure.

FIG. 4A is a schematic top view of another embodiment of the heat dissipation structure of the present disclosure.

FIG. 4B is a partial enlarged schematic view of FIG. 4A.

### DETAILED DESCRIPTION

Implementations of the present disclosure are described below by embodiments. Other advantages and technical effects of the present disclosure can be readily understood by one of ordinary skill in the art upon reading the disclosure of this specification.

It should be noted that the structures, ratios, sizes shown in the drawings appended to this specification are provided in conjunction with the disclosure of this specification in order to facilitate understanding by those skilled in the art. They are not meant, in any ways, to limit the implementations of the present disclosure, and therefore have no substantial technical meaning. Without influencing the effects created and objectives achieved by the present disclosure, any modifications, changes or adjustments to the structures, ratios, or sizes are construed as falling within the scope covered by the technical contents disclosed herein. Meanwhile, terms such as “on,” “above,” “below,” “first,” “second,” “a,” “one,” and the like, are for illustrative purposes, and are not meant to limit the scope implementable by the present disclosure. Any changes or adjustments made to the relative relationships, without substantially modifying the technical contents, are also to be construed as within the scope implementable by the present disclosure.

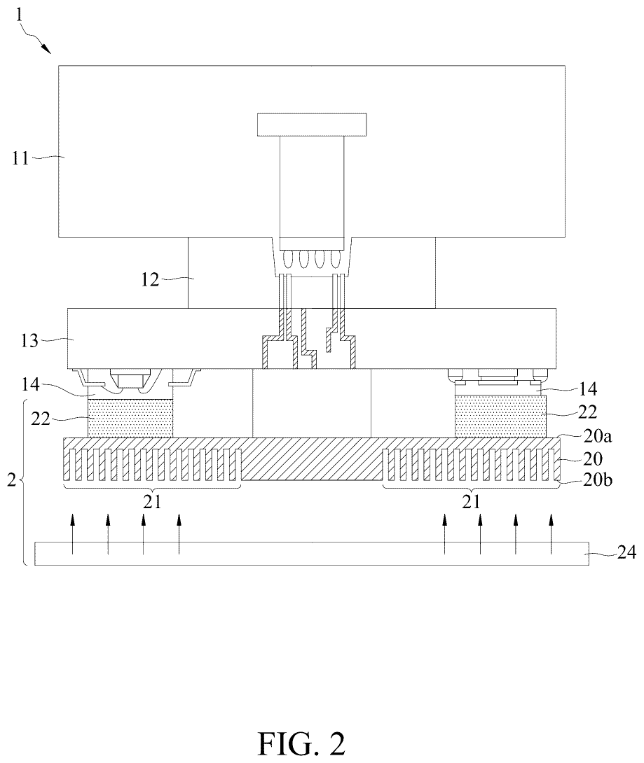

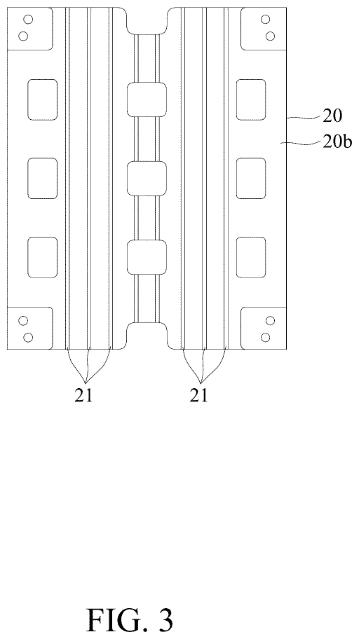

FIG. 2 is an overall schematic view of a heat dissipation structure 2 of the present disclosure disposed in the test apparatus 1, and FIG. 3 is a schematic top view of the heat dissipation structure 2 of the present disclosure. The heat dissipation structure 2 of the present disclosure comprises a board body 20 and bonding portions 22 disposed on the board body 20.

The bonding portions 22 are disposed on the electronic elements 14 on the electronic carrier board 13 of the test apparatus 1.

In an embodiment, the bonding portions 22 are thermal pads (e.g., made of silicone) with high thermal conductivity. In other embodiments, the bonding portions 22 can also be made of material with high thermal conductivity such as graphite, thermal paste, metal strips, etc. The function of the bonding portions 22 is to completely cover and adhere to the surfaces of the electronic elements 14 so as to effectively absorb the heat energy generated by the electronic elements 14.

In an embodiment, the electronic carrier board 13 may be a printed circuit board, and the electronic element 14 may be an active element, a passive element, or a package module, wherein the active element is, for example, a semiconductor chip, and the passive element is, for example, a resistor, a capacitor, or an inductor.

In one embodiment, the quantity of the bonding portions 22 may correspond to the quantity of the electronic elements 14, but the present disclosure is not limited to as such.

Moreover, the board body 20 is generally square and has a first side 20a and a second side 20b opposing the first side 20a. The board body 20 is disposed on the bonding portions 22 via the first side 20a, and heat transfer members 21 are formed on the second side 20b. Therefore, the heat energy generated by the electronic elements 14 can be transferred to the board body 20 via the bonding portions 22, and then transferred from the board body 20 to the heat transfer members 21.

In an embodiment, a material of the board body 20 is a metal alloy, such as aluminum alloy (model 5083) of which thermal conductivity is 155 W/mk, elastic coefficient is 72 GPa, yield strength is 225 MPa, tensile strength is 325 MPa, fatigue strength is 160 MPa, elongation rate at break is 16%, hardness is 77 HB, and thermal expansion rate is 23.4 ppm/° C. The metal alloy can also be aluminum alloy (model 6061) of which thermal conductivity is 167 W/mk, elastic coefficient is 70 GPa, yield strength is 280 MPa, tensile strength is 315 MPa, fatigue strength is 100 MPa, elongation rate at break is 12%, hardness is 95 HB, and thermal expansion rate is 23.6 ppm/° C.

In an embodiment, the heat transfer members 21 are a plurality of fins spaced apart from and parallel to each other, and can be used to dissipate the heat energy generated by the electronic elements 14. The fins may be, for example, skived fins, or other columnar, sheet, or even irregular-shaped fins, as long as the fins can increase the contact area with the air, but the present disclosure is not limited to as such.

The heat dissipation structure 2 of the present disclosure further comprises a blowing member 24. The blowing member 24 is disposed above the second side 20b of the board body 20 and can blow cold air toward the heat transfer members 21 so as to accelerate the dissipation of the heat transferred from the bonding portions 22 to the heat transfer members 21.

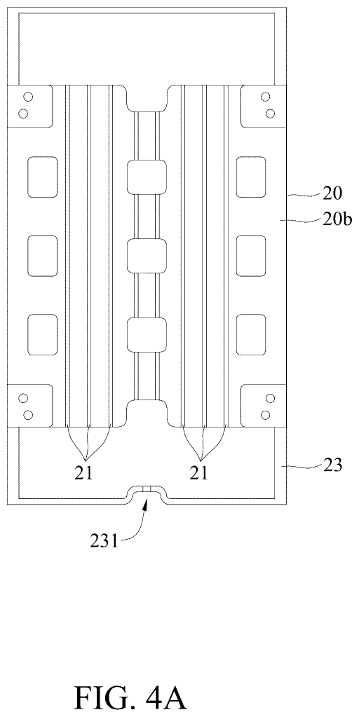

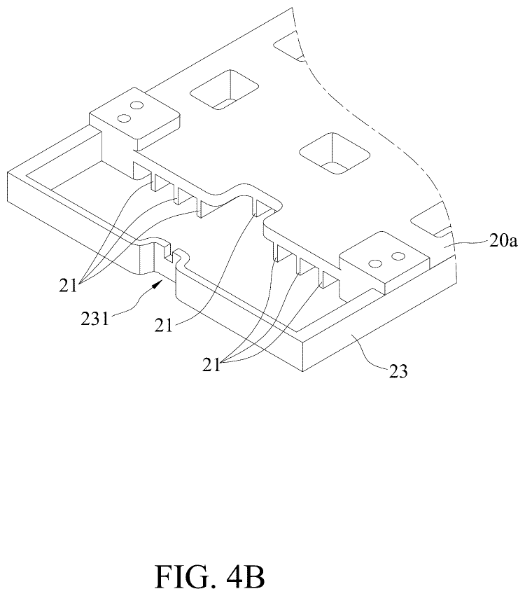

Please refer to FIG. 4A and FIG. 4B. the heat dissipation structure 2 of the present disclosure also comprises a frame 23. The frame 23 may be in a shape of hollow annular and is disposed around the periphery of the board body 20 and has a mounting hole 231 formed by bending from the frame 23. The mounting hole 231 can be used to install thermocouple circuits to prevent the circuits from being crushed when the board body 20 is installed on the test apparatus 1.

In view of the above, the heat dissipation structure of the present disclosure can be disposed on the electronic elements of the electronic carrier board of the test apparatus, which can effectively reduce the temperature of the electronic elements. Compared with the prior art, the present disclosure can reduce the surface temperature of the electronic elements by about 3.55° C. (the prior art is 49.27° C., the present disclosure is 45.72° C.). Therefore, the present disclosure can enable the electronic elements to operate at a lower temperature, and also reduce the service life shortening and damage of the electronic elements caused by temperature, while ensuring the stability and reliability of temperature-sensitive elements during testing. In addition, the board body of the heat dissipation structure of the present disclosure is made of metal alloy, which can also avoid warpage.

The above embodiments are provided for illustrating the principles of the present disclosure and its technical effect, and should not be construed as to limit the present disclosure in any way. The above embodiments can be modified by one of ordinary skill in the art without departing from the spirit and scope of the present disclosure. Therefore, the scope claimed of the present disclosure should be defined by the following claims.

What is claimed is:

1. A heat dissipation structure for a test apparatus, comprising:
bonding portions disposed on electronic elements on an electronic carrier board of the test apparatus; and
a board body having a first side and a second side opposing the first side, wherein the board body is disposed on the bonding portions via the first side and formed with heat transfer members on the second side.

2. The heat dissipation structure of claim 1, wherein a material of the board body is metal alloy.

3. The heat dissipation structure of claim 2, wherein the metal alloy is aluminum alloy.

4. The heat dissipation structure of claim 1, wherein each of the bonding portions is a thermal pad.

5. The heat dissipation structure of claim 1, further comprising a frame surrounding the board body.

6. The heat dissipation structure of claim 5, wherein the frame has a mounting hole for installing thermocouple circuits.

7. The heat dissipation structure of claim 1, wherein each of the heat transfer members is a plurality of fins spaced apart from and parallel to each other.

8. The heat dissipation structure of claim 1, further comprising a blowing member disposed above the second side of the board body and blowing air toward the heat transfer members.
